(19) United States
(12) Patent Application Publication
(10) Pub. No.: US 2021/0335849 A1
(43) Pub. Date: Oct. 28, 2021

(54) TFT ARRAY SUBSTRATE, FABRICATING METHOD THEREOF AND DISPLAY PANEL HAVING THE TFT ARRAY SUBSTRATE

(71) Applicant: SHENZHEN CHINA STAR OPTOELECTRONICS SEMICONDUCTOR DISPLAY TECHNOLOGY CO., LTD, Shenzhen (CN)

(72) Inventors: Nian Liu, Shenzhen (CN); Macai Lu, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/617,619

(22) PCT Filed: May 17, 2019
(86) PCT No.: PCT/CN2019/087409

§ 371 Date: Nov. 27, 2019

(30) Foreign Application Priority Data
Apr. 9, 2019 (CN) 201910278558.9

(51) Int. Cl. H01L 27/12

(52) U.S. Cl. CPC H01L 27/1251; H01L 27/1255; H01L 27/1225; H01L 27/127; H01L 27/1248

(57) ABSTRACT

A thin film transistor (TFT) array substrate includes a substrate layer, wherein a thin film transistor and a capacitor are disposed on the substrate layer and spaced apart from each other, and wherein the thin film transistor includes an active layer made of a metal oxide semiconductor material, and the capacitor includes a semiconductor capacitor electrode made of a metal oxide semiconductor material. The capacitor is coupled to a gate of the thin film transistor, thereby driving the thin film transistor. The TFT array substrate using a novel thin film transistor driving structure, which effectively improves stability of the device.

### FIELD OF INVENTION

The invention relates to the field of flat display technology, in particular, to a TFT array substrate, a fabricating method thereof and a display panel having the TFT array substrate.

### BACKGROUND OF INVENTION

With development of display technology, thin film transistor-liquid crystal displays (TFT-LCDs) are in a dominant position in the display field due to their advantages (low cost, high definition quality, low power consumption, etc.), so they are used in audio-visual equipment such as computers, televisions, and mobile phones.

Structure of the liquid crystal panel is generally composed of a color filter (CF), a thin film transistor (TFT) array substrate, and a liquid crystal layer disposed between the CF and the TFT array substrate. The working principle is to control rotation of the liquid crystal molecules of the liquid crystal layer by applying a driving voltage on the CF and the TFT array substrate, and refract light of backlight module to generate a picture. The thin film transistor in the TFT substrate achieves a display effect by directly controlling the liquid crystals.

Further, with continuous development of technology, the industry has developed metal oxide type thin film transistors, which are used in the next generation display devices due to their high mobility, transparency, and low subthreshold swing.

However, current metal oxide thin film transistors still have stability deficiencies, especially top gate TFTs, which limits their wider development.

Therefore, it is necessary to develop a novel TFT array substrate to overcome the drawbacks of the prior art.

### SUMMARY OF INVENTION

The present invention provides a thin film transistor (TFT) array substrate using a novel thin film transistor driving structure, which effectively improves the stability of the device.

The technical solution adopted by the invention is as follows.

A TFT array substrate includes a substrate layer, wherein a thin film transistor and a capacitor are disposed on the substrate layer and spaced apart from each other, and wherein the thin film transistor includes an active layer made of a metal oxide semiconductor material, and the capacitor includes a semiconductor capacitor electrode made of a metal oxide semiconductor material. The capacitor is coupled to a gate of the thin film transistor, thereby driving the thin film transistor.

Further, in another embodiment, the thin film transistor includes one of a top gate, metal oxide semiconductor thin film transistor, a back channel, metal oxide semiconductor thin film transistor, and an etching stop, metal oxide semiconductor thin film transistor.

Further, in another embodiment, the active layer of the thin film transistor and the semiconductor capacitor electrode of the capacitor are disposed on the same layer and spaced apart from each other.

Further, in another embodiment, materials of the metal oxide semiconductor include one of IGZO (Indium Gallium Zinc Oxide) and IZO (indium-doped zinc oxide).

Further, in another embodiment, the semiconductor electrode of the capacitor is connected to any one of a gate, a drain and an active layer of the thin film transistor. In another embodiment, the semiconductor electrode of the capacitor may not be connected to any one of the gate, the drain and the active layer of the thin film transistor, and may be determined as needed, and is not limited.

Further, in another embodiment, a metal oxide semiconductor layer is disposed on the substrate layer, wherein the metal oxide semiconductor layer includes a first metal oxide semiconductor layer and a second metal oxide semiconductor layer spaced apart from the first metal oxide semiconductor layer, wherein the first metal oxide semiconductor layer is the active layer, and the second metal oxide semiconductor layer is the semiconductor capacitor electrode of the capacitor; wherein a first insulating layer is disposed on the metal oxide semiconductor layer, and a metal layer is disposed on the first insulating layer; wherein the metal layer includes a first metal layer as the gate of the thin film transistor, and a second metal layer as a metal electrode of the capacitor, the first metal layer and the second metal layer are spaced apart from each other; and wherein an interlayer dielectric (ILD) is disposed on the metal layer, and a source metal layer and a drain metal layer are disposed on the ILD and spaced apart from each other.

Further, in another embodiment, a buffer layer is disposed on the substrate layer, and the metal oxide semiconductor layer is disposed on the buffer.

Further, in another embodiment, materials of the buffer layer include at least one of SiOx, SiNx, Al2O3 and AlN.

Further, in another embodiment, the buffer layer is a laminated structure of two or more layers. For example, the buffer layer may be a laminated layer of SiOx/SiNx, a laminated layer of SiNx/SiOx, a laminated layer of SiOx and SiNx, SiNO, a laminated layer of SiOx, SiNx and Al2O3, or a laminated layer of SiOx, SiNx and AlN, and may be specifically determined as needed, but is not limited thereto.

Further, in another embodiment, a light shielding layer is disposed on the substrate layer and in the buffer layer, and a position of the light shielding layer corresponds upward to a position of the first metal oxide semiconductor layer.

Further, in another embodiment, materials of the light shielding layer includes at least one of molybdenum, copper, and aluminum. Specifically, if one of the metal materials is employed, the finished structure is a single-layer structure. If two of the metal materials are employed, a two-layer laminated structure is preferred. Each layer employs a single metal, such as a laminated layer of molybdenum/copper, or a laminated layer of aluminum/molybdenum, but it is not limited thereto.

Further, in another embodiment, the light shielding layer may be in contact with the source metal layer, but is not limited thereto.

Further, in another embodiment, the first metal layer and/or the second metal layer each are a laminated structure of two or more layers.

Further, in another embodiment, materials of the metal layers include at least two of molybdenum, copper, and aluminum.

Further, in another embodiment, the source metal layer and/or the drain metal layer each are a laminated structure of two or more layers.

Further, in another embodiment, material of the ILD layer includes one of SiNx, SiOx, and SiNO.

Further, in another embodiment, a passivation layer is disposed on the ILD layer, and a pixel electrode is disposed on the passivation layer.

Further, in another embodiment, material of the passivation layer includes one of SiNx, SiOx and SiNO.

Further, the present invention provides a method of fabricating a TFT array substrate according to the invention, the fabricating method includes the following steps:

providing a substrate, forming the metal oxide semiconductor layer on the substrate by depositing, and etching the metal oxide semiconductor layer to form the first metal oxide semiconductor layer and the second metal oxide semiconductor layer, wherein the first metal oxide semiconductor layer serves as the active layer of the thin film transistor, the second metal oxide semiconductor layer serves as the semiconductor electrode of the capacitor;

forming the first insulating layer by depositing, forming the metal layer on the first insulating layer by depositing, and etching the metal layer to form the first metal layer serving as the gate of the thin film transistor and the second metal layer serving as the metal electrode of the capacitor;

forming the ILD by depositing, and forming the source metal layer and the drain metal layer on the ILD by depositing.

Further, the present invention provides a display panel, including a TFT array substrate according to the present invention.

Compared with the prior art, the beneficial effects of the present invention are that the invention provides a TFT array substrate, which drives a metal oxide semiconductor thin film transistor by capacitive coupling to a gate, thereby effectively improving the stability of the metal oxide semiconductor thin film transistor. The sensing of the optical signal by the coupling capacitor is used for touch or ambient optical detection, which further expands the application range.

### DESCRIPTION OF DRAWINGS

In order to more clearly illustrate the embodiments of the invention, the drawings used in the embodiments will be briefly described below. Obviously, the drawings in the following description are only for some embodiments of the invention, and other drawings may be obtained from those skilled in the art without any creative work.

FIG. 1 is a schematic view of a TFT driving circuit of a TFT substrate provided in an embodiment of the present invention.

FIG. 2 is a schematic diagram of a TFT substrate provided in another embodiment of the present invention, the TFT disposed thereon is a top gate metal oxide semiconductor thin film transistor.

FIG. 3 is a schematic diagram of a TFT substrate provided in another embodiment of the present invention, the TFT disposed thereon is a back channel metal oxide semiconductor thin film transistor.

FIG. 4 is a schematic diagram of a TFT substrate provided in another embodiment of the present invention, the TFT disposed thereon is a etching stop layer metal oxide semiconductor thin film transistor.

FIG. 5 is a schematic structural diagram after step one of a method for fabricating a TFT substrate according to another embodiment of the present invention.

FIG. 6 is a schematic structural diagram after step two of the method for fabricating a TFT substrate according to the embodiment in FIG. 5.

FIG. 7 is a schematic structural diagram after step three of the method for fabricating a TFT substrate according to the embodiment in FIG. 5.

FIG. 8 is a schematic structural diagram after step four of the method for fabricating a TFT substrate according to the embodiment in FIG. 5.

FIG. 9 is a schematic structural diagram after step five of the method for fabricating a TFT substrate according to the embodiment in FIG. 5.

FIG. 10 is a schematic structural diagram after step six of the method for fabricating a TFT substrate according to the embodiment in FIG. 5.

FIG. 11 is a schematic structural diagram after step seven of the method for fabricating a TFT substrate according to the embodiment in FIG. 5.

### DETAILED DESCRIPTION OF PREFERRED EMBODIMENTS

A TFT array substrate, a fabricating method thereof and a display panel according to the present invention will be further described in detail below with reference to the accompanying drawings and embodiments.

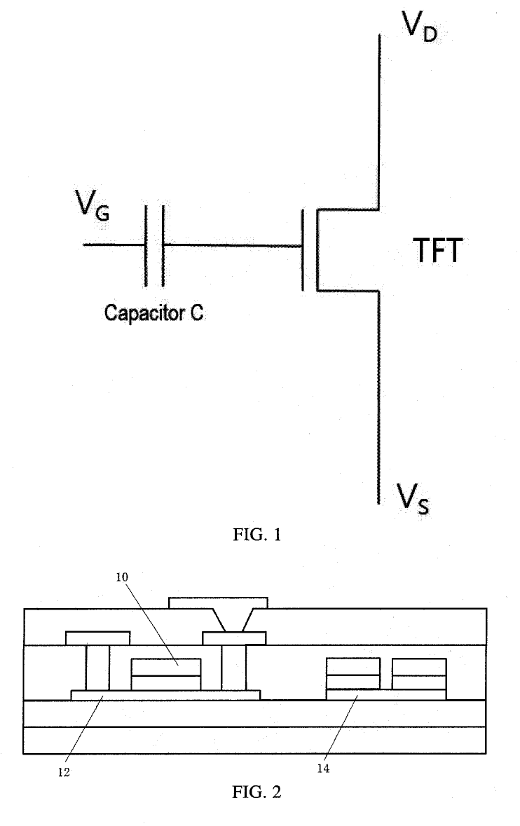

One embodiment of the present invention provides a TFT (thin film transistor) array substrate, including a substrate layer, wherein a thin film transistor and a capacitor are disposed on the substrate layer and spaced apart from each other, and wherein the thin film transistor includes an active layer made of a metal oxide semiconductor material, and the capacitor includes a semiconductor capacitor electrode made of a metal oxide semiconductor material. The capacitor is coupled to a gate of the thin film transistor, thereby driving the thin film transistor, wherein the driving circuit is illustrated in FIG. 1.

Further, in another embodiment, the thin film transistor includes one of a top gate, metal oxide semiconductor thin film transistor, a back channel, metal oxide semiconductor thin film transistor, and an etching stop, metal oxide semiconductor thin film transistor.

Specifically, referring to FIG. 2, a TFT array substrate in an embodiment of the invention is provided, and the thin film transistor is a top gate, metal oxide semiconductor thin film transistor. Wherein the gate 10 of the metal oxide semiconductor thin film transistor is disposed on the active layer 12, and wherein the semiconductor capacitor electrode 14 of the capacitor and the active layer 12 are disposed on the same layer.

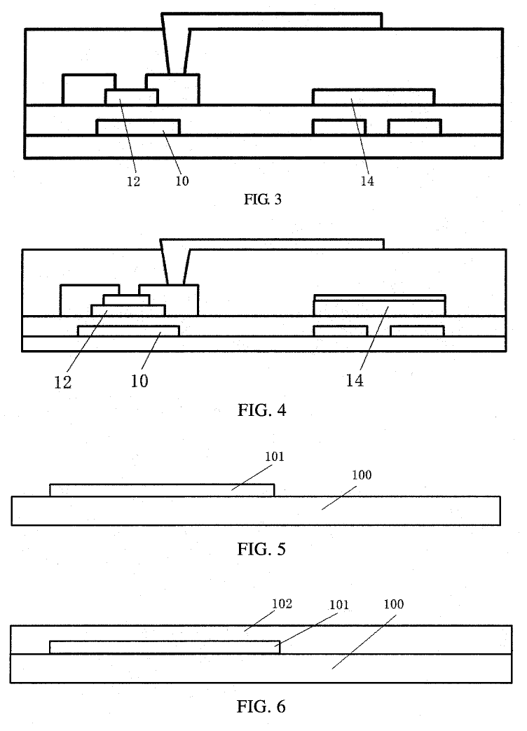

Further, referring to FIG. 3, a TFT array substrate in another embodiment of the invention is provided, and the thin film transistor is a back channel, metal oxide semiconductor thin film transistor. Wherein the gate 10 of the metal oxide semiconductor thin film transistor is disposed above the active layer 12, and wherein the semiconductor capacitor electrode 14 of the capacitor and the active layer 12 are disposed on the same layer.

Further, referring to FIG. 4, a TFT array substrate in another embodiment of the invention is provided, and the thin film transistor is an etching stop, metal oxide semiconductor thin film transistor. Wherein the gate 10 of the metal oxide semiconductor thin film transistor is disposed above the active layer 12, and wherein the semiconductor capacitor electrode 14 of the capacitor and the active layer 12 are disposed on the same layer.

Further, in another embodiment, materials of the metal oxide semiconductor include one of IGZO (Indium Gallium Zinc Oxide) and IZO (indium-doped zinc oxide).

Further, the technical solution according to the present invention will be further described in detail below by taking the above-mentioned TFT array substrate using a top gate, metal oxide semiconductor thin film transistor as an example, and in combination with the fabricating method thereof.

An embodiment of this present invention provides a method of fabricating a TFT array substrate, including the following steps:

Step 1: providing a substrate 100 and disposing a light shielding layer 101 on the substrate 100. The substrate may be a glass substrate, but is not limited thereto. A finished structure is shown in FIG. 5.

Materials of the light shielding layer 101 includes at least one of molybdenum, copper, and aluminum. Specifically, if one of the metal materials is employed, the finished structure is a single-layer structure. If two of the metal materials are employed, a two-layer laminated structure is preferred. Each layer employs a single metal, such as a laminated layer of molybdenum/copper, or a laminated layer of aluminum/molybdenum, but it is not limited thereto.

Step 2: forming a buffer layer 102 by depositing. A finished structure is shown in FIG. 6. Wherein the film structure of the buffer layer may be a single layer structure or a laminated structure, and may be specifically determined as needed, and is not limited thereto.

Specifically, the buffer layer 102 may be a single layer of SiOx, a laminated layer of SiOx/SiNx, a laminated layer of SiNx/SiOx, a laminated layer of SiOx and SiNx, SiNO, a laminated layer of SiOx, SiNx and Al2O3, or a laminated layer of SiOx, SiNx and AlN, but is not limited thereto.

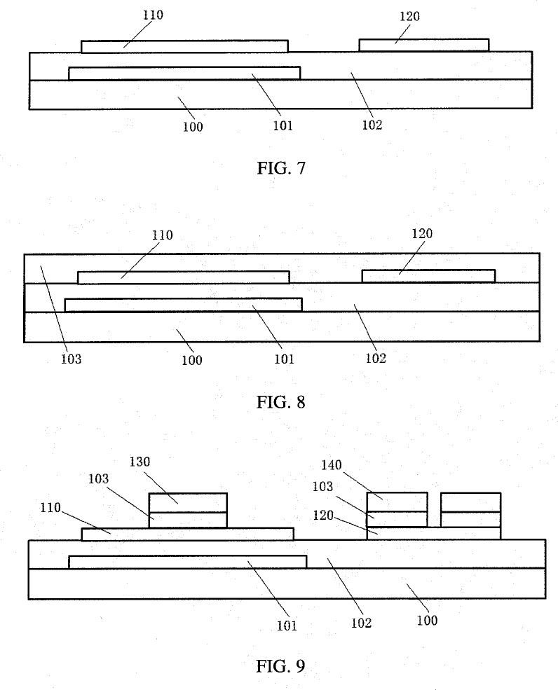

Step 3: depositing IGZO or IZO to form the metal oxide semiconductor layer, and etching the metal oxide semiconductor layer to form a first metal oxide semiconductor layer 110 and a second metal oxide semiconductor layer 120, wherein the first metal oxide semiconductor layer 110 serves as the active layer of the thin film transistor, the second metal oxide semiconductor layer 120 serves as the semiconductor electrode of the capacitor. A finished structure is shown in FIG. 7.

Step 4: forming a first insulating layer 103 by depositing, i.e. a gate insulating layer. A finished structure is shown in FIG. 8. Wherein the film structure of the first insulating layer 103 may be a single layer structure or a laminated structure, and may be specifically determined as needed, and is not limited thereto.

Specifically, the buffer layer 102 may be a single layer of SiOx, a laminated layer of SiOx/SiNx, a laminated layer of SiNx/SiOx, a laminated layer of SiOx and SiNx, SiNO, a laminated layer of SiOx, SiNx and Al2O3, or a laminated layer of SiOx, SiNx and AlN, but is not limited thereto.

Step 5: forming a metal layer by depositing, and etching the metal layer to form a first metal layer 130 serving as the gate of the thin film transistor, and a second metal layer 140 serving as the metal electrode of the capacitor. A finished structure is shown in FIG. 9.

The film structure of the first metal layer 130 or the second metal layer 140 may be a single layer structure or a laminated structure, and may be specifically determined as needed, and is not limited thereto. Specifically, materials of the first metal layer 130 or the second metal layer 140 may be a laminated layer of molybdenum/copper, or a laminated layer of molybdenum/aluminum, but it is not limited thereto.

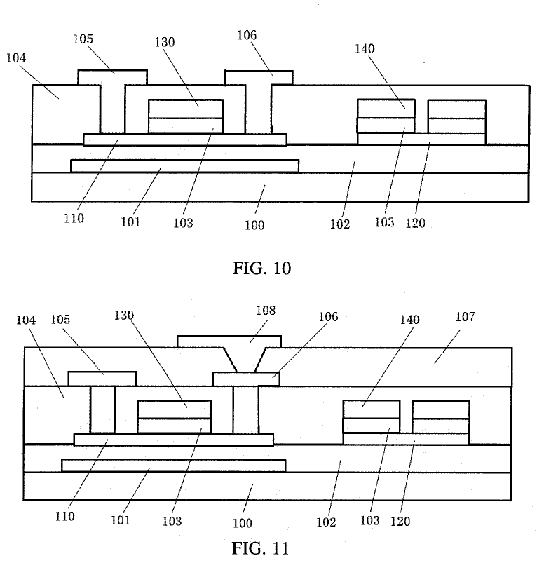

Step 6: forming an interlayer dielectric (ILD) 104 by depositing, forming holes, and forming a source metal layer 105 and a drain metal layer 106 by depositing. A finished structure is shown in FIG. 10.

The film structure of the interlayer dielectric 104 may be a single layer structure or a laminated structure, and may be specifically determined as needed, and is not limited thereto. Specifically, materials of the interlayer dielectric 104 may be at least one of SiNx, SiOx, and SiNO.

The film structures of the source metal layer 105 or the drain metal layer 106 may be a single layer structure or a laminated structure, and may be specifically determined as needed, and is not limited thereto. For example, the source metal layer 105 or the drain metal layer 106 may specifically be a laminated layer of molybdenum/copper, a laminated layer of molybdenum/aluminum, or the like, but is not limited thereto. Further, in another embodiment, the source metal layer may be connected to the light shielding layer through the holes downward, but is not limited thereto.

Step 7: forming a passivation layer (PV) 107 by depositing, forming vias, and forming a pixel electrode 108 by depositing. A finished structure is shown in FIG. 11. Meanwhile, FIG. 11 also shows an overall structure of the TFT array substrate according to the present invention, which employs a top gate, metal oxide semiconductor thin film transistor.

The film structure of the passivation layer 107 may be a single layer structure or a laminated structure, and may be specifically determined as needed, and is not limited thereto. Specifically, materials of the passivation layer 107 may be at least one of SiNx, SiOx, and SiNO. The pixel electrode 108 is preferably made of ITO (Indium tin oxide), but is not limited thereto.

Further, another embodiment of the present invention provides a display panel, including the TFT array substrate according to the invention.

The invention provides a TFT array substrate, which drives a metal oxide semiconductor thin film transistor by capacitive coupling to a gate, thereby effectively improving the stability of the metal oxide semiconductor thin film transistor. The sensing of the optical signal by the coupling capacitor is used for touch or ambient optical detection, which further expands the application range.

The technical scope of the present invention is not limited to the above description, and those skilled in the art can make various modifications and changes to the above embodiments without departing from the technical idea of the present invention. These modifications and changes are intended to be within the scope of the invention.

What is claimed is:

1. A thin film transistor (TFT) array substrate, comprising:
a substrate layer, wherein a thin film transistor and a capacitor are disposed on the substrate layer and spaced apart from each other;
wherein the thin film transistor comprises an active layer made of a metal oxide semiconductor material, and the capacitor comprises a semiconductor capacitor electrode made of a metal oxide semiconductor material; and
wherein the capacitor is coupled to a gate of the thin film transistor, thereby driving the thin film transistor.

2. The TFT array substrate as claimed in claim 1, wherein the thin film transistor comprises one of a top gate, metal oxide semiconductor thin film transistor, a back channel, metal oxide semiconductor thin film transistor, and an etching stop, metal oxide semiconductor thin film transistor.

3. The TFT array substrate as claimed in claim 1, wherein the active layer of the thin film transistor and the semiconductor capacitor electrode of the capacitor are disposed on a same layer and spaced apart from each other.

4. The TFT array substrate as claimed in claim 1, wherein a metal oxide semiconductor layer is disposed on the substrate layer, wherein the metal oxide semiconductor layer comprises a first metal oxide semiconductor layer and a second metal oxide semiconductor layer spaced apart from the first metal oxide semiconductor layer, wherein the first metal oxide semiconductor layer is the active layer, and the second metal oxide semiconductor layer is the semiconductor capacitor electrode of the capacitor;
wherein a first insulating layer is disposed on the metal oxide semiconductor layer, and a metal layer is disposed on the first insulating layer; wherein the metal layer comprises a first metal layer as the gate of the thin film transistor, and a second metal layer as a metal electrode of the capacitor, the first metal layer and the second metal layer are spaced apart from each other; and
wherein an interlayer dielectric (ILD) is disposed on the metal layer, and a source metal layer and a drain metal layer are disposed on the ILD and spaced apart from each other.

5. The TFT array substrate as claimed in claim 4, wherein a buffer layer is disposed on the substrate layer, and the metal oxide semiconductor layer is disposed on the buffer, wherein the buffer layer is a laminated structure of two or more layers.

6. The TFT array substrate as claimed in claim 5, wherein a light shielding layer is disposed on the substrate layer and in the buffer layer, and a position of the light shielding layer corresponds upward to a position of the first metal oxide semiconductor layer.

7. The TFT array substrate as claimed in claim 4, wherein the first metal layer and/or the second metal layer each are a laminated structure of two or more layers.

8. The TFT array substrate as claimed in claim 4, wherein the source metal layer and/or the drain metal layer each are a laminated structure of two or more layers.

9. A method of fabricating a TFT array substrate as claimed in claim 4, comprising the following steps:
providing a substrate, forming the metal oxide semiconductor layer on the substrate by depositing, and etching the metal oxide semiconductor layer to form the first metal oxide semiconductor layer and the second metal oxide semiconductor layer, wherein the first metal oxide semiconductor layer serves as the active layer of the thin film transistor, the second metal oxide semiconductor layer serves as the semiconductor electrode of the capacitor;
forming the first insulating layer by depositing, forming the metal layer on the first insulating layer by depositing, and etching the metal layer to form the first metal layer serving as the gate of the thin film transistor and the second metal layer serving as the metal electrode of the capacitor;
forming the ILD by depositing, and forming the source metal layer and the drain metal layer on the ILD by depositing.

10. A display panel, comprising a TFT array substrate as claimed in claim 1.
